(19) United States
(12) Patent Application Publication
(10) Pub. No.: US 2024/0006388 A1
(43) Pub. Date: Jan. 4, 2024

(54) DISPLAY MODULE

(71) Applicant: KORTEK CORPORATION, Incheon (KR)

(72) Inventors: Hak Hyun KIM, Incheon (KR); Woo HWANGBO, Yongin-si, Gyeonggi-do (KR)

(21) Appl. No.: 18/271,781

(22) PCT Filed: Mar. 18, 2021
(86) PCT No.: PCT/KR2021/003330

§ 371 Date: Jul. 11, 2023

(51) Int. Cl. H01L 25/13

(52) U.S. Cl. CPC H01L 25/13

(57) ABSTRACT

A display module is provided, and the display module includes: a circuit board unit on which a plurality of LED units are arranged; and a plurality of holder units supporting the circuit board unit, and arranged to be spaced apart from each other such that the circuit board unit is curved to be rounded in a first direction and a second direction.

### CROSS-REFERENCE TO RELATED APPLICATIONS

This application claims priority to PCT Application No. PCT/KR2021/003330, having a filing date of Mar. 18, 2021, the entire contents of which are hereby incorporated by reference.

### FIELD OF TECHNOLOGY

The following relates to a display module, and more specifically, to a display module which may be installed to be bidirectionally curved, and may implement a flexibly rounded display screen when bidirectionally curved.

### BACKGROUND

Generally, display modules are applied to advertisement panels, display panels, large panels, and the like. The display modules are arranged in a matrix form in a cabinet unit. A plurality of display modules can be arranged to form a plane or a curved surface. The display module includes a display panel and a support. The plurality of display modules can display one image or individually display a plurality of images.

However, since a conventional display module is formed with a structure which is flexible only in one direction (for example, a transverse direction), a display screen curved in the transverse direction can be implemented, but a display screen curved in a longitudinal direction cannot be implemented.

Further, since the display panel is supported by a plurality of supports disposed side by side in the longitudinal direction, when the display panel is curved in the transverse direction, a plurality of bent lines of which corresponding portions between the supports in the display panel are bent at a predetermined angle are formed. Accordingly, since flat portions and bent lines are alternately formed along the transverse direction in the conventional display module, it was difficult to implement a display screen which is flexibly rounded with a constant curvature.

Further, since the plurality of bent lines parallel to the longitudinal direction are formed in the display panel, stress concentration occurs in bent line portions of the display panel. Accordingly, as the bent lines or surface-mounted elements arranged near the bent lines are damaged due to the stress concentration, it can cause a failure of the display module.

The background art is disclosed in Korean Laid-Open Patent Application No. 2009-0090541 (released on Aug. 26, 2009, Title of the invention: Display device for outdoor advertisement).

### SUMMARY

An aspect relates to a display module which may be installed to be bidirectionally curved, and may implement a flexibly rounded display screen when bidirectionally curved.

A display module according to embodiments of the present invention include: a circuit board unit on which a plurality of light-emitting diode (LED) units are arranged; and a plurality of holder units configured to support the circuit board unit, and arranged to be spaced apart from each other so that the circuit board unit is curved to be rounded in a first direction and a second direction.

The circuit board unit may include: a circuit board body portion on which the plurality of LED units are arranged; and a plurality of coupling portions arranged to form a plurality of rows on a rear surface portion of the circuit board body portion, and to which the holder units are coupled.

The plurality of holder units may be arranged in the circuit board body portion in a matrix form.

Each of the holder units may include: a holder body portion; a contact surface portion formed in the holder body portion to come into contact with the circuit board body portion; and a separation surface portion formed in a perimeter portion of the holder body portion to be spaced apart from the circuit board body portion.

The contact surface portion may be formed in a flat shape.

The separation surface portion may be formed to be rounded.

The separation surface portion may be formed in the perimeter portion of the holder body portion in each of the second direction and the first direction.

An interval between the separation surface portion and the circuit board body portion may increase toward the outside from the contact surface portion.

The display module may further include connection portions configured to connect the plurality of holder units in a row.

The connection portions may be formed in a band shape.

The connection portions may be formed in a rounded shape.

An opening may be formed in the holder unit to dissipate heat from the circuit board unit.

The display module may further include a magnet portion fastened to the holder unit.

The display module may further include a position alignment portion installed in the holder unit to correct an installation position of the circuit board unit.

The display module may further include a gasket portion installed between the circuit board unit and the plurality of holder units.

The gasket portion may include: support portions arranged in a matrix form to respectively support the plurality of holder units; and insertion portions formed between the support portions to protrude to be fitted between the plurality of holder units.

A communication hole portion may be formed in the support portion to dissipate heat from the circuit board unit.

The communication hole portion may communicate with an opening of the holder unit.

### Advantageous Effects

According to the embodiments of the present invention, a display module can be installed to be bidirectionally curved, and can implement a flexibly rounded display screen when bidirectionally curved.

Further, according to embodiments of the present invention, since a circuit board unit is curved with a constant curvature, stress can be uniformly applied to the entire circuit board unit. Accordingly, as stress concentration is prevented from locally occurring in the circuit board unit, a cause of a failure of the display module can be eliminated.

Further, according to embodiments of the present invention, when the display module is curved in a first direction or a second direction, the formation of a plurality of bent lines which are bent at a predetermined angle in a display unit can be prevented. Further, the display module can implement a display screen which is flexibly rounded with a constant curvature.

### BRIEF DESCRIPTION

Some of the embodiments will be described in detail, with reference to the following figures, wherein like designations denote like members, wherein:

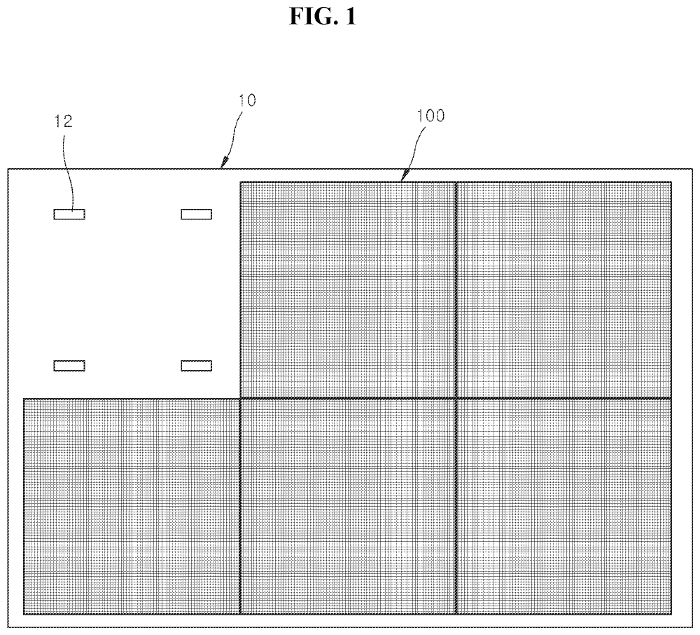

FIG. 1 is a plan view illustrating a state in which display modules according to one embodiment of the present invention are installed in a cabinet unit;

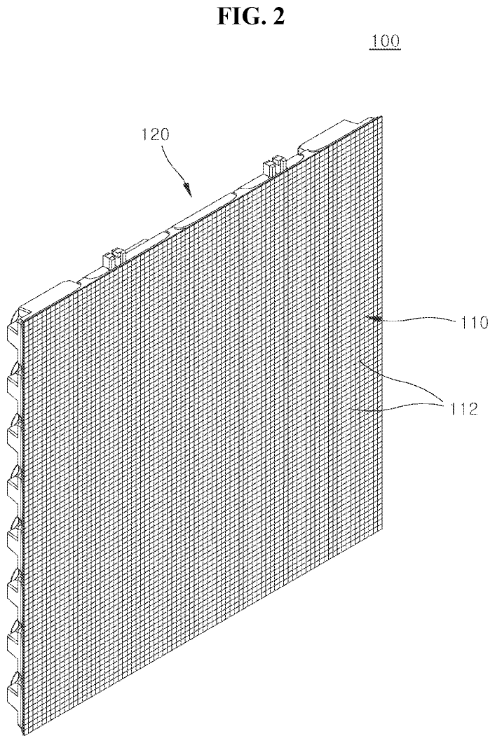

FIG. 2 is a perspective view illustrating the display module according to one embodiment of the present invention;

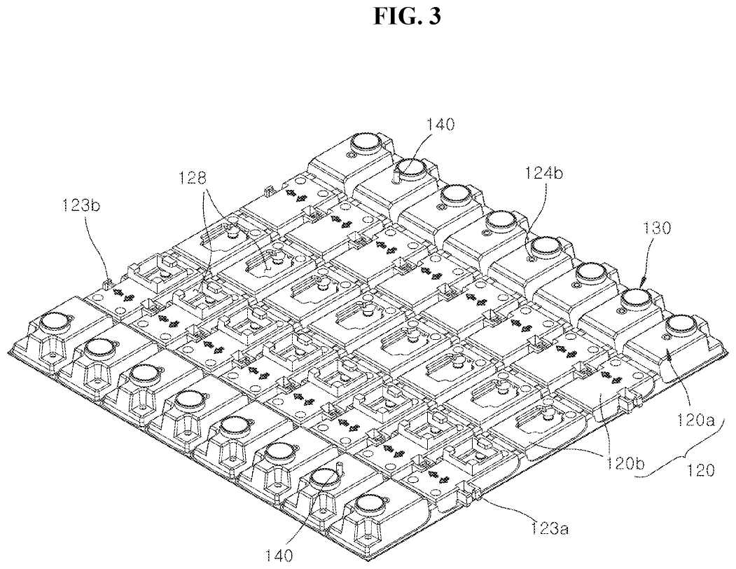

FIG. 3 is a perspective view illustrating a rear side of the display module according to one embodiment of the present invention;

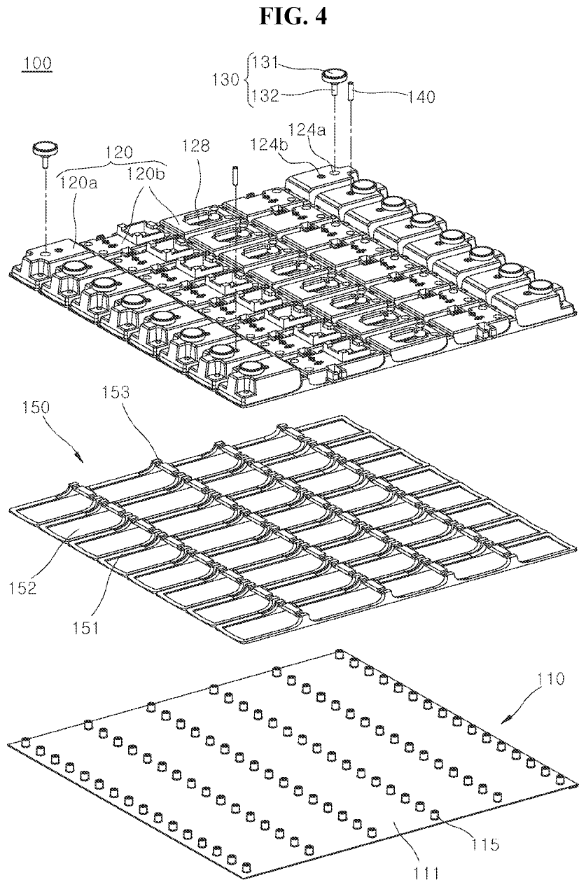

FIG. 4 is an exploded perspective view illustrating the display module according to one embodiment of the present invention;

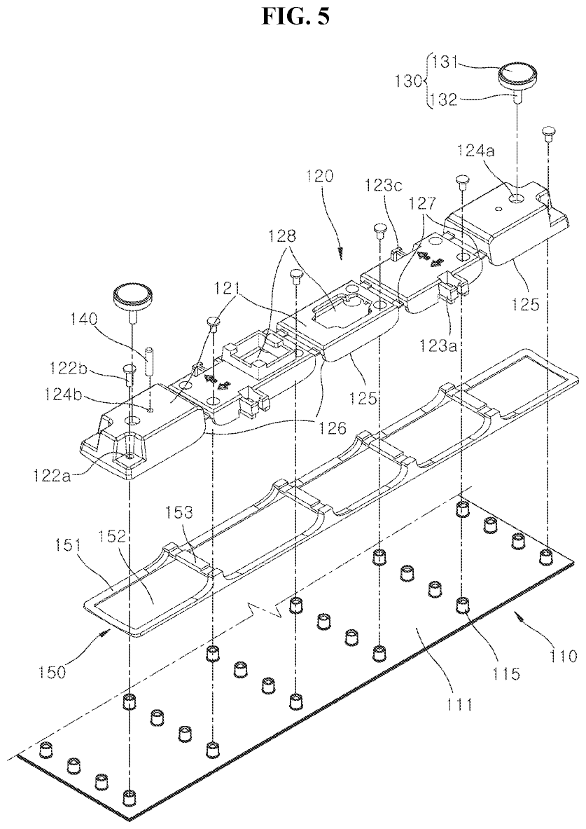

FIG. 5 is a perspective view illustrating an assembly structure of the display module according to one embodiment of the present invention;

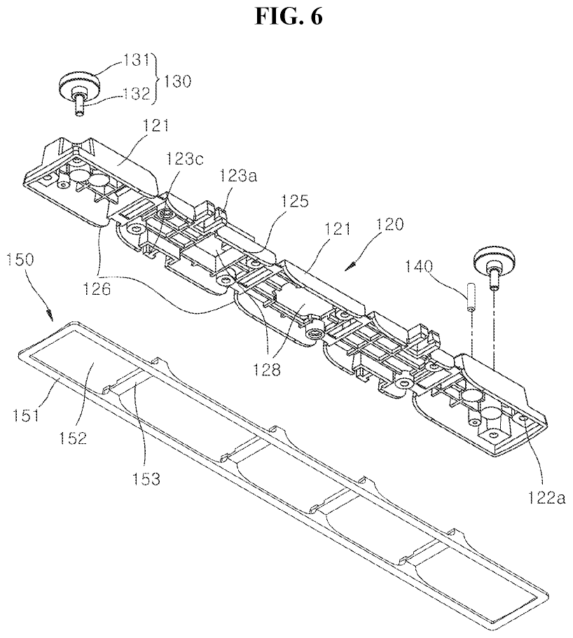

FIG. 6 is a perspective view illustrating a holder unit and a gasket portion in the display module according to one embodiment of the present invention;

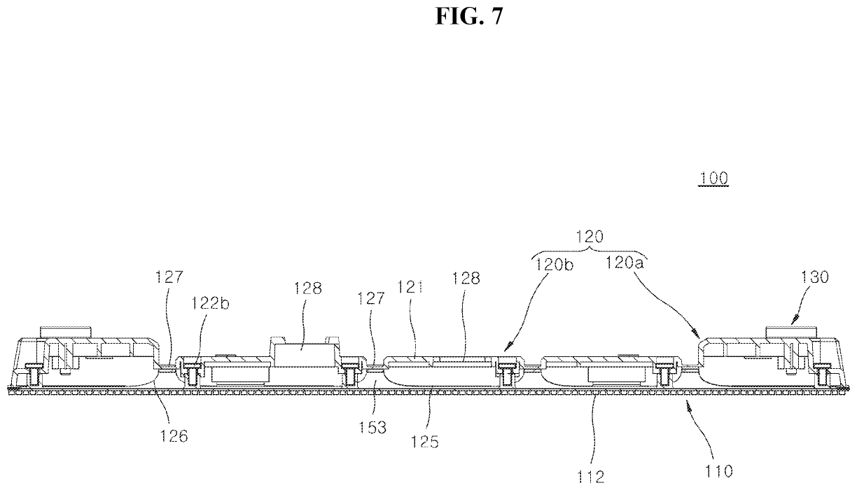

FIG. 7 is a view illustrating a first direction of the display module according to one embodiment of the present invention;

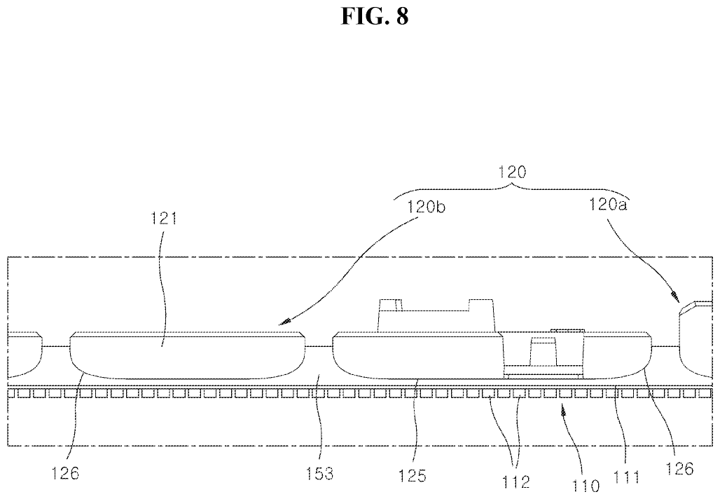

FIG. 8 is an enlarged view illustrating the first direction of the display module according to one embodiment of the present invention;

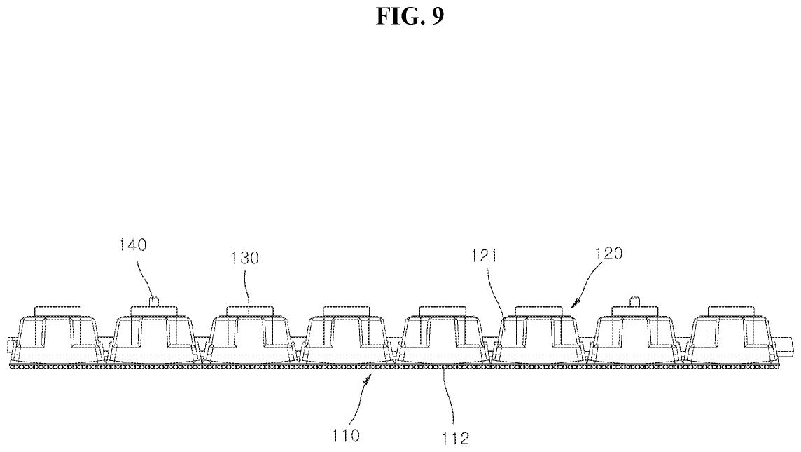

FIG. 9 is a view illustrating a second direction of the display module according to one embodiment of the present invention;

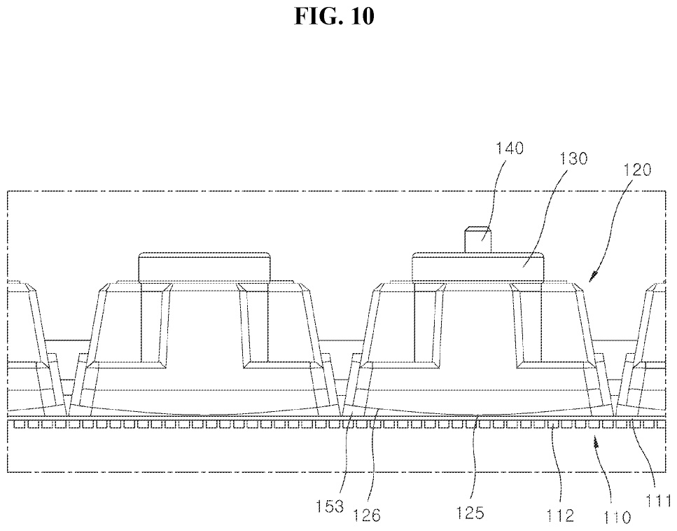

FIG. 10 is an enlarged view illustrating the second direction of the display module according to one embodiment of the present invention;

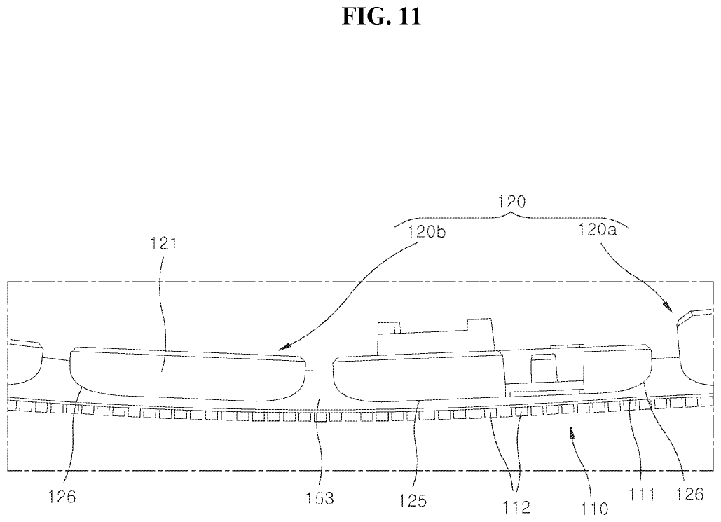

FIG. 11 is a view illustrating a state in which the display module according to one embodiment of the present invention is curved in the first direction;

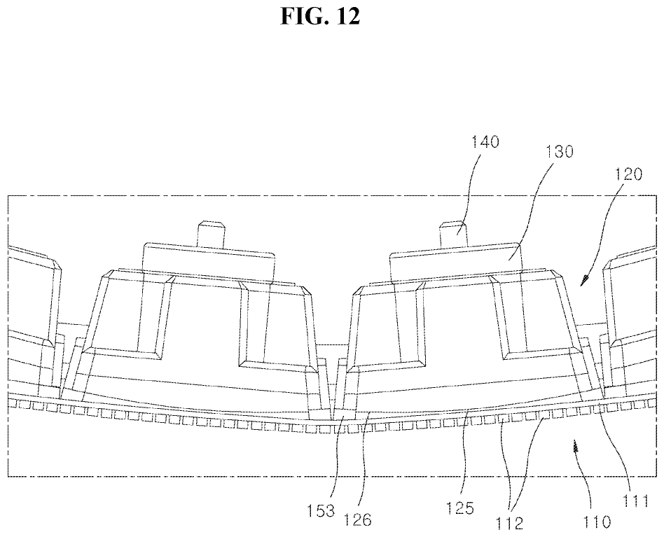

FIG. 12 is a view illustrating a state in which the display module according to one embodiment of the present invention is curved in the second direction;

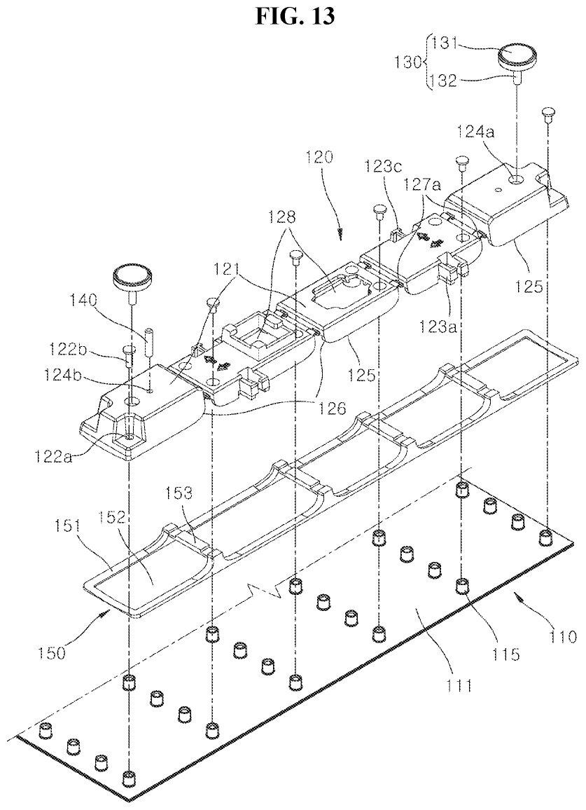

FIG. 13 is a perspective view illustrating an assembly structure of a display module according to another embodiment of the present invention;

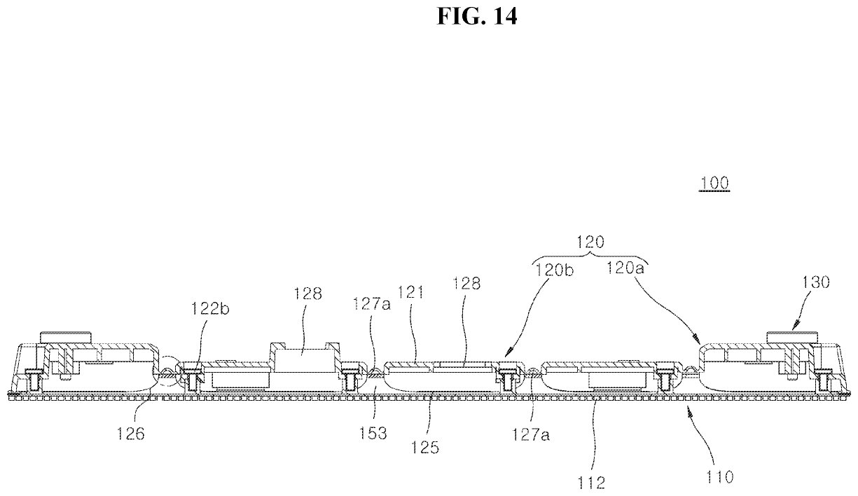

FIG. 14 is a view illustrating a first direction of the display module according to another embodiment of the present invention; and

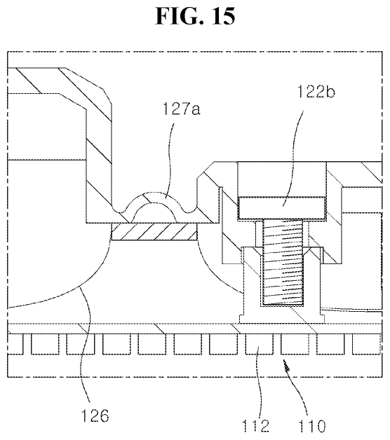

FIG. 15 is an enlarged view illustrating a connection portion of the display module according to another embodiment of the present invention.

### DETAILED DESCRIPTION

In the process of describing the display module, the thickness of lines, the size of components, or the like shown in the drawings may be shown to be exaggerated for clarity and convenience of description. Further, terms to be described below are terms defined in consideration of functions in embodiments of the present invention, and thus may be changed according to intentions or customs of users and operators. Accordingly, the definition of these terms should be made based on the content throughout the present specification.

First, display modules according to one embodiment of the present invention will be described.

FIG. 1 is a plan view illustrating a state in which the display modules according to one embodiment of the present invention are installed in a cabinet unit, FIG. 2 is a perspective view illustrating the display module according to one embodiment of the present invention, FIG. 3 is a perspective view illustrating a rear side of the display module according to one embodiment of the present invention, FIG. 4 is an exploded perspective view illustrating the display module according to one embodiment of the present invention, FIG. 5 is a perspective view illustrating an assembly structure of the display module according to one embodiment of the present invention, FIG. 6 is a perspective view illustrating a holder unit and a gasket portion in the display module according to one embodiment of the present invention, FIG. 7 is a view illustrating a first direction of the display module according to one embodiment of the present invention, FIG. 8 is an enlarged view illustrating the first direction of the display module according to one embodiment of the present invention, FIG. 9 is a view illustrating a second direction of the display module according to one embodiment of the present invention, FIG. 10 is an enlarged view illustrating the second direction of the display module according to one embodiment of the present invention, FIG. 11 is a view illustrating a state in which the display module according to one embodiment of the present invention is curved in the first direction, and FIG. 12 is a view illustrating the second direction of the display module according to one embodiment of the present invention.

Referring to FIGS. 1 to 12, a display module 100 according to one embodiment of the present invention includes a circuit board unit 110 and a plurality of holder units 120.

The display modules 100 are arranged in a matrix form in a cabinet to form an advertisement panel, a display panel, and a large panel. A plurality of long hole portions 12 disposed side by side in the first direction are formed in the cabinet to correct an installation position of the display modules 100.

A plurality of light-emitting diode (LED) units 112 are arranged on the circuit board unit 110. The plurality of LED units 112 are arranged in a matrix form on the circuit board unit 110. A circuit pattern (not shown) is formed in the circuit board unit 110 to supply power to the plurality of LED units 112.

The plurality of holder units 120 support the circuit board unit, and are arranged to be spaced apart from each other so that the circuit board unit 110 is curved to be rounded in the first direction and the second direction. In this case, the circuit board unit 110 may be convexly curved toward the front side or convexly curved toward the rear side. Further, a portion of the circuit board unit 110 may be curved, and the remaining portion of the circuit board may maintain a flat plate shape. Since the circuit board unit 110 is curved to be rounded in the first direction and the second direction, the display module 100 may be applied to advertisement panels, display panels, large panels, and the like that are curved in the first direction or the second direction. Here, the first direction and the second direction include a transverse direction and a longitudinal direction, directions perpendicular to each other, or inclined directions which are not perpendicular to each other.

Further, when the display module 100 is curved in the first direction or the second direction, the formation of a plurality of bent lines which are bent at a predetermined angle in the circuit board unit 110 may be prevented. Accordingly, the display module 100 according to embodiments of the present invention may implement a display screen which is flexibly rounded with a constant curvature. Further, the display module 100 is curved to be rounded in the second direction and the first direction, and thus may be applied to various types of curved display devices and may implement an original design.

Further, since the circuit board unit 110 is curved with a constant curvature, stress may be uniformly applied to the circuit board unit 110. Accordingly, as stress concentration is prevented from locally occurring in the circuit board unit 110, a cause of a failure of the display module 100 may be eliminated.

The circuit board unit 110 includes a circuit board body portion 111 and a plurality of coupling portions 115.

The plurality of LED units 112 are arranged on the circuit board body portion 111. The circuit board body portion 111 is formed in a rectangular plate shape. The plurality of LED units 112 are arranged in a matrix form on the circuit board body portion 111. Various electronic modules such as a transformer, a controller, and the like are installed on the circuit board body portion 111.

The plurality of coupling portions 115 are arranged to form a plurality of rows on a rear surface portion of the circuit board body portion 111, and the holder units 120 are coupled to the plurality of coupling portions 115. The plurality of coupling portions 115 may be arranged in the plurality of rows along the first direction or the second direction. The coupling portions 115 may be fixed to the circuit board body portion 111 by welding or may be detachably coupled to the circuit board body portion 111. In this case, positions of the plurality of coupling portions 115 may be variously changed according to a position of an electronic module such as a converter or the like installed on the circuit board body portion 111.

The plurality of holder units 120 are arranged on the circuit board body portion 111 in a matrix form. Since the plurality of coupling portions 115 are arranged on the circuit board body portion 111 to form a plurality of rows, the plurality of holder units 120 may be arranged in a matrix form on a rear side of the circuit board body portion 111. Further, the length or width of the plurality of holder units 120 may be changed according to an arrangement interval of the coupling portions 115. The plurality of holder units 120 are arranged on the circuit board body portion 111 in a matrix form, and thus may be flexibly deformed so that the circuit board unit 110 may form a circular arc of a constant curvature when curved in the first direction and the second direction.

Arrows in upward and downward directions and arrows in leftward and rightward directions may be formed on rear surface portions of the plurality of holder units 120 to recognize upward and downward directions and leftward and rightward directions of the display module 100. Accordingly, it may easy for a worker to visually check an installation direction of the display module 100.

The holder unit 120 includes holder body portions 121, contact surface portions 125 formed in the holder body portion 121 to come into contact with the circuit board body portion 111, and separation surface portions 126 formed in perimeter portions of the holder body portion 121 to be spaced apart from the circuit board body portion 111. In this case, the holder unit 120 includes a holder unit 120a arranged on a perimeter portion of the circuit board body portion 111 and holder units 120b arranged inside the circuit board body portion 111.

Since the contact surface portions 125 come into contact with the circuit board body portion 111, the LED units 112 facing the contact surface portions 125, electronic modules, and soldering portions may be stably supported by the circuit board body portion 111, and cracks may be prevented from occurring in the circuit board body portion 111. Further, since the separation surface portions 126 are formed in the perimeter portions of the holder body portion 121, when the display module 100 is installed on a curved display device, the circuit board body portion 111 is bent while flexibly forming a circular arc. Accordingly, stress concentration in the LED units 112 facing the separation surface portions 126 in the circuit board body portion 111 may be prevented.

The contact surface portion 125 is formed in a flat shape. The contact surface portion 125 may be formed with an appropriate length according to the curvature of the curved display device. Since the contact surface portion 125 is formed in a flat shape, a supporting force of the circuit board body portion 111 may be sufficiently secured.

The separation surface portion 126 is formed to be rounded. In this case, the separation surface portion 126 may be formed in a circular arc shape or a shape similar thereto. Since the separation surface portion 126 is formed in a rounded shape, when the circuit board body portion 111 is bent, the circuit board body portion 111 may be supported by some of the separation surface portions 126, and the circuit board body portion 111 may be prevented from being locally bent.

The separation surface portion 126 is formed in perimeter portions of holder body portion 121 in each of the first direction and the second direction. In this case, the contact surface portion 125 is formed inside the separation surface portion 126 in a bottom surface of the holder body portion 121. Since the separation surface portion 126 is formed in the perimeter portions of holder body portion 121 in each of the first direction and the second direction, the circuit board unit 110 may be bent to form a smooth curvature in the first direction and the second direction.

An interval between the separation surface portion 126 and the circuit board body portion 111 increases toward the outside from the contact surface portion 125. Accordingly, when the circuit board body portion 111 is bent, a contact area between the separation surface portion 126 and the circuit board body portion 111 is changed according to the curvature of the circuit board body portion 111.

A coupling hook portion 123a is formed at one side of each of some of the holder units 120, and a coupling rib 123c is formed at the other side of each of some of the holder units 120. As the coupling rib 123c is coupled to the coupling hook portion 123a, the plurality of holder units 120 may be connected to each other. Further, the coupling hook portion 123a and the coupling rib 123c may be formed at the outside of the holder unit 120a arranged on the perimeter portion of the circuit board unit 110. Accordingly, the plurality of display modules 100 may be connected in the second direction and the first direction by the coupling hook portions 123a and the coupling ribs 123c.

The display module 100 further includes connection portions 127 which connect the plurality of holder units 120 in a row. In this case, the connection portion 127 may be arranged between the holder units 120 and formed in a band shape. Further, the connection portion 127 may be formed of the same material as the holder unit 120 or may be formed of a different material from the holder unit 120. The number of connections of the holder units 120 may be changed according to the size of the circuit board unit 110. Since the connection portions 127 connect the plurality of holder units 120 in a row, the plurality of holder units 120 arranged in a row may be easily assembled on the circuit board unit 110, and the assembly time of the display module 100 may be shortened. Further, since the plurality of holder units 120 are supported by the connection portions 127, a change in assembly position of the plurality of holder units 120 may be prevented.

Openings 128 are formed in the holder unit 120 to dissipate heat from the circuit board unit 110. The openings 128 may be formed in various shapes. Further, a connector portion (not shown) may be installed through the opening 128. Accordingly, the connector portion may be easily installed on the circuit board body portion 111, and heat generated from the circuit board body portion 111 and the LED units 112 may be discharged through the openings 128.

The display module 100 further includes a magnet portion 130 fastened to the holder unit 120. The magnet portion 130 includes a magnet head portion 131 and a magnet fastening portion 132. In this case, a magnet coupling hole portion 124a is formed in the holder unit 120 so that the magnet fastening portion 132 is coupled thereto. A magnetic force is formed in the magnet head portion 131, and the magnet fastening portion 132 is formed in a screw shape. Since the magnet portion 130 is fastened to the magnet coupling hole portion 124a of the holder unit 120, the display module 100 may be assembled in a state of being attached to a cabinet unit 10 by the magnetic force. Accordingly, assembly of the display module 100 may be improved.

The display module 100 further includes position alignment portions 140 installed in the holder units 120 so that an installation position of the circuit board unit 110 may be corrected. The number of position alignment portions 140 may be variously changed according to the shape and size of the circuit board unit 110. In this case, alignment portion coupling holes 124b are formed in the holder units 120, and the position alignment portions 140 are fitted into the alignment portion coupling holes 124b. Further, as the alignment portion coupling holes 124 are formed in all of the holder units 120, the installation position of the position alignment portions 140 nay be variously changed. The position alignment portions 140 are inserted into the long hole portions 12 of the cabinet unit 10. Accordingly, since the positions of the plurality of display modules 100 are corrected while the position alignment portions 140 are moved in the long hole portions 12 of the cabinet unit 10, assembly of the plurality of display modules 100 in a twisted state in the first direction and the second direction due to an assembly tolerance of the display module 100 may be prevented.

The display module 100 further includes a gasket portion 150 installed between the circuit board unit 110 and the plurality of holder units 120. The gasket portion 150 may be formed of a flexible material such as rubber, a sponge, silicone, or the like, or may be formed of a porous material capable of shielding electromagnetic waves. Since the gasket portion 150 is formed of a flexible material, the circuit board unit 110 may be bent in a flexible circular arc shape. Since the gasket portion 150 seals a gap between the holder units 120 and the circuit board unit 110, the penetration of foreign matter between the circuit board unit 110 and the holder units 120 may be prevented. Further, electromagnetic interference (EMI), electromagnetic compatibility (EMC), and the like which occur in the circuit board unit 110 may be blocked. Accordingly, damage to the circuit board unit 110 or the LED units 112 by static electricity, sparks, or the like may be prevented.

The gasket portion 150 includes support portions 151 arranged in a matrix form to respectively support the plurality of holder units 120, and insertion portions 153 formed between the support portions 151 to protrude to be fitted between the plurality of holder units 120. The insertion portion 153 is formed in a round shape to come into close contact with the separation surface portion 126 of the holder unit 120. Since the support portions 151 are formed in a matrix form, the holder units 120 may be seated on the support portions 151. Further, since the insertion portions 153 are inserted between the plurality of holder units 120, the plurality of holder units 120 may be more stably seated at the installation position.

A communication hole portion 152 is formed inside the support portion 151 to dissipate heat from the circuit board unit 110. The communication hole portions 152 may be formed in the holder units 120b except for the holder units 120a arranged on the perimeter portion of the circuit board unit 110. Accordingly, the entire circuit board unit 110 may be evenly cooled.

The communication hole portion 152 communicates with the opening 128 of the holder unit 120. Accordingly, since the heat discharged from the circuit board unit 110 and the LED units 112 may be discharged to the outside through the communication hole portions 152 and the openings 128, heat dissipation performance of the display module 100 may be further improved.

Next, a display module according to another embodiment of the present invention will be described. Since another embodiment of the present invention is substantially the same as in the above-described one embodiment except for connection portions, the same reference numerals are given to the same components and descriptions thereof will be omitted.

FIG. 13 is a perspective view illustrating an assembly structure of the display module according to another embodiment of the present invention, FIG. 14 is a view illustrating a first direction of the display module according to another embodiment of the present invention, and FIG. 15 is an enlarged view illustrating a connection portion of the display module according to another embodiment of the present invention.

Referring to FIGS. 13 to 15, the display module 100 further includes connection portions 127a which connect a plurality of holder units 120 in a row. The connection portions 127a is arranged between the holder units 120. The connection portions 127a may be formed to be round to be softly and elastically deformed. In this case, the connection portions 127a may be formed in a convex circular arc shape toward a rear side of a circuit board unit 110 or may be formed in a convex circular arc shape toward a front side of the circuit board unit 110. The number of connections of the holder units 120 may be changed according to the size of the circuit board unit 110. Since the connection portions 127a connect the plurality of holder units 120 in a row, the plurality of holder units 120 arranged in a row may be easily assembled on the circuit board unit 110, and the assembly time of the display module 100 may be shortened. Further, since the plurality of holder units 120 are supported by the connection portions 127a, a change in assembly position of the plurality of holder units 120 may be prevented. Further, since the connection portions 127a are formed to be rounded, the connection portions 127a may be gathered or spread out due to elasticity when the circuit board unit 110 is bent to be curved.

Although the present invention has been disclosed in the form of embodiments and variations thereon, it will be understood that numerous additional modifications and variations could be made thereto without departing from the scope of the invention.

For the sake of clarity, it is to be understood that the use of “a” or “an” throughout this application does not exclude a plurality, and “comprising” does not exclude other steps or elements. The mention of a “unit” or a “module” does not preclude the use of more than one unit or module.

1. A display module comprising:
a circuit board unit on which a plurality of light-emitting diode (LED) units are arranged; and
a plurality of holder units configured to support the circuit board unit, and arranged to be spaced apart from each other so that the circuit board unit is curved to be rounded in a first direction and a second direction.

2. The display module of claim 1, wherein the circuit board unit includes:
a circuit board body portion on which the plurality of LED units are arranged; and
a plurality of coupling portions arranged to form a plurality of rows on a rear surface portion of the circuit board body portion, and to which the holder units are coupled.

3. The display module of claim 2, wherein the plurality of holder units are arranged on the circuit board body portion in a matrix form.

4. The display module of claim 3, wherein each of the holder units includes:
a holder body portion;
a contact surface portion formed in the holder body portion to come into contact with the circuit board body portion; and
a separation surface portion formed in a perimeter portion of the holder body portion to be spaced apart from the circuit board body portion.

5. The display module of claim 4, wherein the contact surface portion is formed in a flat shape.

6. The display module of claim 4, wherein the separation surface portion is formed to be rounded.

7. The display module of claim 6, wherein the separation surface portion is formed in the perimeter portion of the holder body portion in each of the second direction and the first direction.

8. The display module of claim 6, wherein an interval between the separation surface portion and the circuit board body portion increases toward the outside from the contact surface portion.

9. The display module of claim 3, further comprising connection portions configured to connect the plurality of holder units in a row.

10. The display module of claim 9, wherein the connection portions are formed in a band shape.

11. The display module of claim 9, wherein the connection portions are formed in a rounded shape.

12. The display module of claim 3, wherein an opening is formed in the holder unit to dissipate heat from the circuit board unit.

13. The display module of claim 3, further comprising a magnet portion fastened to the holder unit.

14. The display module of claim 3, further comprising a position alignment portion installed in the holder unit to correct an installation position of the circuit board unit.

15. The display module of claim 1, further comprising a gasket portion installed between the circuit board unit and the plurality of holder units.

16. The display module of claim 15, wherein the gasket portion includes:
support portions arranged in a matrix form to respectively support the plurality of holder units; and
insertion portions formed between the support portions to protrude to be fitted between the plurality of holder units.

17. The display module of claim 15, wherein a communication hole portion is formed in the support portion to dissipate heat from the circuit board unit.

18. The display module of claim 17, wherein the communication hole portion communicates with an opening of the holder unit.
